(19) United States
(12) Patent Application Publication
(10) Pub. No.: US 2025/0021000 A1
(43) Pub. Date: Jan. 16, 2025

(54) COMPOSITION

(71) Applicant: Merck Patent GmbH, Darmstadt (DE)

(72) Inventors: Seishi SHIBAYAMA, Kakegawa-shi (JP); Daishi YOKOYAMA, Kakegawa-Shi (JP); Atsuko NOYA, Kakegawa-shi (JP)

(21) Appl. No.: 18/708,629

(22) PCT Filed: Nov. 9, 2022
(86) PCT No.: PCT/EP2022/081192

§ 371 Date: May 9, 2024

(30) Foreign Application Priority Data
Nov. 12, 2021 (JP) 2021-185126

(51) Int. Cl. G03F 7/027; G03F 7/004; G03F 7/039; G03F 7/16

(52) U.S. Cl. CPC G03F 7/027; G03F 7/0048; G03F 7/039; G03F 7/168

(57) ABSTRACT

A composition containing an alkali-soluble material, a cured film and a manufacturing method thereof.

### BACKGROUND OF THE INVENTION

### Technical Field

The present invention relates to a composition containing an alkali-soluble material. The present invention also relates to a method for manufacturing a cured film using the same, a cured film formed therefrom, a light conversion device comprising the cured film, and a display device comprising the light conversion device.

### Background Art

Black matrices for color filters used in color display devices are formed by mixing a light shielding black pigment such as carbon black with an alkali-soluble resin to form a resist composition, which is then coated, and the coated film is exposed, developed and patterned. Black matrices are used, for example, in a liquid crystal display device to prevent light leakage from non-switching pixels and maintain high contrast. Since amorphous silicon and oxide semiconductors generate leakage current due to photoexcitation when exposed to light, the black matrix layer suppresses the leakage current by blocking the light to the thin film transistor portion (Patent Document 1).

### PRIOR ART DOCUMENTS

### Patent Documents

[Patent document 1] JP 2018-203599 A

### SUMMARY OF THE INVENTION

### Problems to be Solved by the Invention

Surprisingly, the present inventors have found that there are one or more significant problems that are desired to be improved, as listed below.

To provide a composition capable of forming a cured film that exhibits oil repellency at its upper part and lipophilicity at its lower part;
to provide a patternable composition for forming a bank that exhibits oil repellency at the top of the bank and lipophilicity at the bottom of the bank;
to provide a patternable composition that preferably exhibits, after bank formation, oil repellency at the top of the bank and lipophilicity at the opening and the side of the bank;
to provide a bank that exhibits lipophilicity to ink at the opening of the bank, preferably allows ink to be filled without any gap at the opening of the bank, and exhibits lipophilicity to ink at the top of the bank, preferably repels ink appropriately at the top of the bank, and/or to provide a patternable composition for forming the above bank, wherein preferably, the above ink is a quantum dot-containing ink, more preferably the above ink is an acrylic monomer-containing ink, further preferably the above ink is solvent-free;
to provide a composition capable of curing and being patterned under lower temperature condition than that for conventional compositions;
to provide a composition comprising a pigment that does not adversely affect patterning, where preferably the pigment is a black pigment;
to provide a composition capable of being patterned with high resolution;
to provide a composition capable of achieving a thicker film as a partition wall material for a display device;
to provide a composition preferably containing a black pigment capable of achieving a thicker film as a partition wall material for a display device; and
to provide a composition capable of being developed with a low-concentration alkaline developer other than an organic developer, which is environment-friendly.

### Means for Solving the Problems

As a result of earnest investigation, the present inventors found a composition comprising:
(I) an alkali-soluble material;
(II) a first surfactant; and
(III) a second surfactant different from the first surfactant.

In another aspect, the present invention relates to a method for manufacturing a cured film comprising:
a step of applying the above composition above a substrate to form a coating film; and
a step of heating the coating film.

In another aspect, the present invention relates to a cured film produced or capable of being produced by the above method.

In another aspect, the present invention relates to a cured film comprising:
a polymer (A) derived from an alkali-soluble material;
a first surfactant; and
a second surfactant different from the first surfactant.

In another aspect, the present invention relates to a light conversion device comprising the above cured film.

In another aspect, the present invention relates to a display device comprising the above cured film or the above light conversion device.

### Effects of the Invention

According to the present invention, one or more of the following effects can be desired.

To provide a composition capable of forming a cured film that exhibits oil repellency at its upper part and lipophilicity at its lower part;
to provide a patternable composition for forming a bank that exhibits oil repellency at the top of the bank and lipophilicity at the bottom of the bank;
to provide a patternable composition that preferably exhibits, after bank formation, oil repellency at the top of the bank and lipophilicity at the opening and the side of the bank;
to provide a bank that exhibits lipophilicity to ink at the opening of the bank, preferably allows ink to be filled without any gap at the opening of the bank, and exhibits lipophilicity to ink at the top of the bank, preferably repels ink appropriately at the top of the bank, and/or to provide a patternable composition for forming the above bank, wherein preferably, the above ink is a quantum dot-containing ink, more preferably the above ink is an acrylic monomer-containing ink, further preferably the above ink is solvent-free;
to provide a composition capable of curing and being patterned under lower temperature condition than that for conventional compositions; and
to provide a composition comprising a pigment that does not adversely affect patterning, where preferably the pigment is a black pigment.

### DETAILED DESCRIPTION OF THE INVENTION

### Mode for Carrying Out the Invention

Further advantages of the present invention become apparent from the detailed description below. However, the foregoing summary and the following details are intended to explain the present invention and are not intended to limit the invention as claimed.

### Definitions

Unless otherwise specified in the present specification, symbols, units, abbreviations and terms have the following meanings.

Unless otherwise specified in the present specification, the singular form includes the plural form and “one” or “that” means “at least one”. Unless otherwise specified in the present specification, an element of a concept can be expressed by a plurality of species, and when the amount (for example, mass % or mol %) is described, it means sum of the plurality of species. “And/or” includes a combination of all elements and also includes single use of the element.

In the present specification, when a numerical range is indicated using “to” or “-”, it includes both endpoints and units thereof are common. For example, 5 to 25 mol % means 5 mol % or more and 25 mol % or less.

In the present specification, the (meth)acrylate means acrylate, methacrylate, or a mixture of acrylate and methacrylate according to common general technical knowledge.

In the present specification, the monomer means a monomeric substance, and refers to a substance that can form a polymer (including an oligomer) by reacting with another monomer.

In the present specification, the polymer may be in the form of an oligomer, and the mass average molecular weight of the polymer is not particularly limited, but is preferably 1,000 to 100,000, more preferably 2,000 to 30,000. The mass average molecular weight is a mass average molecular weight in terms of styrene obtained by the gel permeation chromatography.

In the present specification, the alkyl means a group obtained by removing any one hydrogen from a linear or branched, saturated hydrocarbon and includes a linear alkyl and branched alkyl, and the cycloalkyl means a group obtained by removing one hydrogen from a saturated hydrocarbon comprising a cyclic structure and optionally includes a linear or branched alkyl in the cyclic structure as a side chain.

In the present specification, the aryl means a group obtained by removing any one hydrogen from an aromatic hydrocarbon. The alkylene means a group obtained by removing any two hydrogens from a linear or branched, saturated hydrocarbon. The arylene means a hydrocarbon group obtained by removing any two hydrogens from an aromatic hydrocarbon.

In the present specification, the descriptions such as “C_{x-y}”, “Cₓ-C_{y}” and “Cₓ” mean the number of carbons in a molecule or substituent. For example, C₁₋₆ alkyl means alkyl having 1 or more and 6 or less carbons (methyl, ethyl, propyl, butyl, pentyl, hexyl etc.). The fluoroalkyl used in the present specification refers to alkyl in which one or more hydrogen atoms are replaced with fluorine, and the fluoroaryl refers to aryl in which one or more hydrogen atoms are replaced with fluorine.

In the present specification, when polymer has plural types of repeating units, these repeating units copolymerize. These copolymerization may be any of alternating copolymerization, random copolymerization, block copolymerization, graft copolymerization, or a mixture thereof.

In the present specification, % means mass %, and ratio means mass ratio.

In the present specification, Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (VI) or another component.

### <Composition>

The composition according to the present invention comprises:
(I) an alkali-soluble material;
(II) a first surfactant; and
(III) a second surfactant different from the first surfactant.

In one embodiment of the present invention, the present invention essentially consists of (I) an alkali-soluble material, (II) a first surfactant, and (III) a second surfactant different from the first surfactant, and in another embodiment of the present invention, the present invention consists of (I) an alkali-soluble material, (II) a first surfactant, and (III) a second surfactant different from the first surfactant.

The composition according to the present invention is preferably a film forming composition, more preferably a cured film forming composition.

The composition according to the present invention is preferably a photosensitive composition, more preferably a negative type photosensitive composition.

Preferably, the composition according to the present invention further comprises:
(IV) a coloring agent (preferably organic coloring agent and/or inorganic coloring agent, more preferably organic and/or inorganic black coloring agent);
(V) a polymerization initiator; and/or
(VI) a solvent.

The composition according to the present invention exhibits a better effect when forming a film of 100 μm or less, and is preferably a negative type photosensitive composition for thick film, which exhibits a greater effect when forming a thick film.

### (I) Alkali-Soluble Material

The composition according to the present invention comprises an alkali-soluble material.

The alkali-soluble material is an alkali-soluble monomer, an alkali-soluble polymer, or a mixture thereof.

The alkali-soluble material preferably has a partial structure with an acid group. The acid group is preferably an acid group having an acid dissociation index (pKa) of 7 or less, more preferably —OH, —COOH, —SO₃H, —OSO₃H, —PO₃H₂, —OPO₃H₂, —CONHSO₂ and —SO₂NHSO₂—, and —COOH is particularly preferred. Having an acid group, preferably a carboxy group, can effectively improve the solubility of the alkali-soluble material in a low-concentration developer.

When the alkali-soluble material is an alkali-soluble monomer, the alkali-soluble monomer is a compound containing, preferably one or more, more preferably two or more (meth)acryloyloxy groups. Preferably, the alkali-soluble material is a compound containing two or more (meth)acryloyloxy groups and/or an alkali-soluble polymer.

More preferably, the alkali-soluble material comprises a compound containing two or more (meth)acryloyloxy groups, and further preferably further comprises an alkali-soluble polymer.

### Compound Containing Two or More (Meth)acryloyloxy Groups

A compound containing two or more (meth)acryloyloxy groups is hereinafter sometimes referred to as the (meth)acryloyloxy group-containing compound for the sake of simplicity. The (meth)acryloyloxy group is a general term for an acryloyloxy group and a methacryloyloxy group. This compound is a compound capable of forming a crosslinked structure by reacting with an acryloyl group-containing compound, an alkali-soluble polymer, or the like. In order to form a crosslinked structure, a compound containing two or more acryloyloxy groups or methacryloyloxy groups that are reactive groups is required, and in order to form a higher-order crosslinked structure, three or more acryloyloxy groups or methacryloyloxy groups are preferably contained.

As such a compound containing two or more (meth)acryloyloxy groups, esters obtained by reacting (α) a polyol compound having two or more hydroxyl groups and (β) two or more (meth)acrylic acids are preferably used.

As such a polyol compound (α), a compound that has a saturated or unsaturated aliphatic hydrocarbon, an aromatic hydrocarbon, a heterocyclic hydrocarbon, a primary, secondary or tertiary amine, an ether, or the like as a basic skeleton, and two or more hydroxyl groups as a substituent is included. This polyol compound may contain other substituents such as a carboxy group, a carbonyl group, an amino group, an ether bond, a thiol group, a thioether bond, etc., in such a range that is not detrimental to the effect of the present invention.

Preferred polyol compounds include alkylpolyol, arylpolyol, polyalkanolamine, cyanuric acid, dipentaerythritol, or the like.

When the polyol compound (α) has 3 or more hydroxyl groups, not all the hydroxyl groups need to be reacted with (meth)acrylic acid and may be partially esterified. That is, these esters may have unreacted hydroxyl groups. Examples of such esters include tris(2-acryloxyethyl) isocyanurate, dipentaerythritol hexa(meth)acrylate, tripentaerythritol octa(meth)acrylate, pentaerythritol tetra(meth)acrylate, dipropylene glycol diacrylate, tripropylene glycol diacrylate, trimethylolpropane triacrylate, polytetramethylene glycol dimethacrylate, trimethylolpropane trimethacrylate, ditrimethylolpropane tetraacrylate, tricyclodecane dimethanol diacrylate, 1,9-nonanediol diacrylate, 1,6-hexanediol diacrylate, 1,10-decanediol diacrylate, and the like. Among these, tris(2-acryloxyethyl) isocyanurate and dipentaerythritol hexaacrylate are preferred from the viewpoint of reactivity and the number of crosslinkable groups. Two or more types of these compounds can be combined in order to adjust the shape of the pattern to be formed. In particular, it is preferable to combine a compound containing three (meth)acryloyloxy groups and a compound containing two (meth)acryloyloxy groups.

From the viewpoint of reactivity, such a compound is preferably a molecule that is relatively smaller than the alkali-soluble polymer. For this reason, the molecular weight thereof is preferably 2,000 or less, more preferably 1,500 or less.

The content of the (meth)acryloyloxy group-containing compound is adjusted depending on the type of the polymer and acryloyloxy group-containing compound used, etc., but it is preferably 5 to 99.9 mass %, more preferably 30 to 70 mass %, based on the total mass of the composition excluding the solvent. When it is combined with an alkali-soluble polymer, from the viewpoint of the compatibility with the alkali-soluble polymer, it is preferably 5 to 1,000 mass %, more preferably 10 to 800 mass %, based on the total mass of the alkali-soluble polymer. When a low-concentration developer is used, it is preferably 30 to 800 mass %. The (meth)acryloyloxy group-containing compound may be used alone or in combination of two or more.

### Alkali-Soluble Polymer

For the alkali-soluble polymer, it is desirable to select a polymer that dissolves in an organic solvent such as propylene glycol monomethyl ether acetate (hereinafter referred to as PGMEA), exhibits water solubility, and dissolves in an alkaline developer before exposure.

Preferably, the alkali-soluble polymer has a structural portion having an acid group, and is more preferably a polymer obtained by copolymerizing the structural portion having an acid group and a structural portion having no acid group.

The acid group is preferably an acid group having an acid dissociation index (pKa) of 7 or less, more preferably —OH, —COOH, —SO₃H, —OSO₃H, —PO₃H₂, —OPO₃H₂, —CONHSO₂ and —SO₂NHSO₂—, and —COOH is particularly preferred. Having an acid group, preferably a carboxy group, can effectively improve the solubility of the alkali-soluble material in a low-concentration developer.

The alkali-soluble polymer (which may be in the form of an oligomer) used in the present invention preferably comprises an acryloyl group.

Preferably, the alkali-soluble polymer consists of (meth)acrylic polymer, siloxane polymer, siloxane (meth)acrylic polymer, or a mixture thereof, and the alkali-soluble polymer used in the present invention is not particularly limited, but is preferably selected from polysiloxane containing siloxane bonds in the main skeleton, and (meth)acrylic polymer. Among these, it is more preferable to use (meth)acrylic polymer from the viewpoint of capable of being suitably used for low-temperature processes. Acrylic polymer is more preferred.

The alkali dissolution rate of an alkali-soluble polymer is measured and calculated as follows, using a 0.03 mass % KOH (potassium hydroxide) aqueous solution as the alkali solution.

The alkali-soluble polymer is diluted with PGMEA to become 35 mass %, and dissolved at room temperature with stirring for 1 hour using a stirrer. In a clean room at a temperature of 23.0±0.5° C. and a humidity of 50±5.0%, 1 cc of the prepared alkali-soluble polymer solution is dropped onto the center portion of a silicon wafer (4-inch and thickness: 525 μm) using a pipette and spin-coated to become a thickness of 2±0.1 μm, followed by heating on a hot plate at 100° C. for 90 seconds to remove the solvent. The film thickness of the coating film is measured with a spectroscopic ellipsometer (J. A. Woollam).

Next, after the silicon wafer having this film is gently immersed in a 6-inch diameter glass petri dish containing 100 ml of a 0.03 mass % KOH aqueous solution adjusted to 23.0±0.1° C., it is left to stand, and the time until the coating film disappears is measured. The dissolution rate is obtained by dividing by the time required for the film at 10 mm inside from the edge of the wafer to disappear. When the dissolution rate is remarkably slow, after the wafer is immersed in a KOH aqueous solution for a certain period of time, the film thickness is measured, and the dissolution rate is calculated by dividing the amount of change in film thickness before and after the immersion by the immersion time. The above measurement method is performed 5 times, and the average of the obtained values is taken as the dissolution rate of the alkali-soluble polymer.

Preferably, the alkali-soluble polymer is referred to one in which the coating film at 10 mm inside from the edge of the wafer dissolves and disappears in a 0.03 mass % KOH aqueous solution within 10 minutes in the above measurement and calculation of the alkali dissolution rate.

### (Polysiloxane)

The alkali-soluble polymer may contain a siloxane (Si—O—Si) bond as its main skeleton. In the present invention, a polymer containing siloxane bonds as a main skeleton is referred to as polysiloxane. Depending on the number of oxygen atoms bonded to a silicon atom, the skeleton structure of a polysiloxane can be classified into a silicone skeleton (the number of oxygen atoms bonded to a silicon atom is 2), a silsesquioxane skeleton (the number of oxygen atoms bonded to a silicon atom is 3), and a silica skeleton (the number of oxygen atoms bonded to a silicon atom is 4). In the present invention, any of these may be used. The polysiloxane molecule may contain a plurality of combinations of any of these skeleton structures. Preferably, the polysiloxane used in the present invention contains a silsesquioxane skeleton.

A polysiloxane generally has a silanol group or an alkoxysilyl group. Such a silanol group and alkoxysilyl group mean a hydroxyl group and alkoxy group directly bonded to a silicon forming the siloxane skeleton. The silanol group and the alkoxysilyl group can be thought that they have the effect of promoting the curing reaction when forming a cured film using the composition and also contribute to the reaction with the silicon-containing compound described later. For this reason, it is preferable that polysiloxane has these groups.

### (Acrylic Polymer)

The acrylic polymer suitably used in the present invention can be selected from generally used acrylic polymer, such as polyacrylic acid, polymethacrylic acid, polyalkyl acrylate and polyalkyl methacrylate. As an example, the acrylic polymer used in the present invention preferably contains a repeating unit containing an acryloyl group, and preferably the acrylic polymer has a structural portion having an acid group.

The acid group is preferably an acid group having an acid dissociation index (pKa) of 7 or less, more preferably —OH, —COOH, —SO₃H, —OSO₃H, —PO₃H₂, —OPO₃H₂, —CONHSO₂ and —SO₂NHSO₂—, and —COOH is particularly preferred. Having an acid group, preferably a carboxy group, can effectively improve the solubility of the alkali-soluble material in a low-concentration developer.

The polymerization unit containing an acid group (for example, carboxyl group, etc.) is not particularly limited as long as it is a polymerization unit containing an acid group in its side chain, but polymerization units, which are derived from an unsaturated carboxylic acid, an unsaturated carboxylic acid anhydride or a mixture thereof, are preferred.

The polymerization unit containing an alkoxysilyl group may be a polymerization unit containing an alkoxysilyl group in its side chain, but polymerization units derived from a monomer represented by the following formula (B) is preferable:

X^{B}—(CH₂)ₐ—Si(OR^{B})_{b}(CH₃)_{3-b} (B)
where X^{B} is a vinyl group, a styryl group or a (meth)acryloyloxy group, and R^{B} is a methyl group or an ethyl group, a is an integer of 0 to 3, and b is an integer of 1 to 3.

The polymer preferably contains a polymerization unit containing a hydroxyl group derived from a hydroxyl group-containing unsaturated monomer.

The mass average molecular weight of the alkali-soluble polymer according to the present invention, which is preferably an acrylic polymer, is not particularly limited, but is preferably 1,000 to 40,000, more preferably 2,000 to 30,000. The mass average molecular weight is a mass average molecular weight in terms of styrene obtained by gel permeation chromatography. Further, from the viewpoint of enabling development with a low-concentration alkaline developer and achieving both reactivity and storage stability, as to the number of acid groups, the solid content acid value is usually 40 to 190 mgKOH/g, more preferably 60 to 150 mgKOH/g.

When the composition according to the present invention is a photosensitive composition, a cured film is formed on a substrate through coating, exposure and development. At this time, it is necessary that a difference in solubility between the exposed and unexposed areas occurs, and the coating film in the unexposed areas should have a certain level of solubility in the developer. For example, it can be thought that if the dissolution rate of the coating film in a 2.38 mass % KOH aqueous solution (hereinafter sometimes referred to as alkali dissolution rate or ADR, and details is described later) after prebaked is 50 Å/sec or more, pattern formation by exposure-development is possible. However, since the required solubility differs depending on the average film thickness of the cured film to be formed and the development conditions, the alkali-soluble polymer should be appropriately selected according to the development conditions. Although it varies depending on the type and amount of the photosensitizer and silanol condensation catalyst contained in the composition, for example, if the average film thickness is 0.1 to 100 μm (1,000 to 1,000,000 Å), the dissolution rate in a 2.38 mass % KOH aqueous solution is preferably 50 to 20,000 Å/sec, more preferably 100 to 10,000 Å/sec.

Although the polysiloxane and acrylic polymer used in the present invention are not particularly limited, and for example, the polysiloxane and acrylic polymer, etc. described in WO2021/018927A1 can be suitably used.

The alkali-soluble polymer may be one or a mixture of two or more. Combinations of acrylic polymer and polysiloxane, two or more types of acrylic polymer, two or more types of polysiloxane, etc. can also be used.

In a preferred embodiment, from the viewpoint of being able to form a film and a cured film at a low temperature, the alkali-soluble polymer used in the present invention is one or a mixture of two or more acrylic polymer, more preferably two acrylic polymer. More preferably, as the alkali-soluble polymer, it is desirable to select two types of acrylic polymer such that dissolves in an organic solvent such as PGMEA, exhibits water solubility, and dissolves in an alkaline developer before exposure. Further preferably, the two types of acrylic polymer each has a structural portion having an acid group and is more preferably a polymer obtained by copolymerizing a structural portion having an acid group and a structural portion having no acid group.

The acid group is preferably an acid group having an acid dissociation index (pka) of 7 or less, more preferably —OH, —COOH, —SO₃H, —OSO₃H, —PO₃H₂, —OPO₃H₂, —CONHSO₂ and —SO₂NHSO₂—, and —COOH is particularly preferred.

The total content of the alkali-soluble material (I) in the composition is preferably 5 to 99.9 mass %, more preferably 70 to 90 mass %, based on the total mass of the composition excluding the solvent.

### (II) First Surfactant

The composition according to the present invention comprises a first surfactant (II). In the present invention, the first surfactant (II) is not particularly limited as long as it achieves at least one or more of the effects of the present invention, but from the viewpoint of enabling to provide a composition that exhibits lipophilicity at least in the lower part of the film formed, preferably to provide a composition that exhibits lipophilicity at least at the bottom of the bank or the bottom of the bank and the bank side of the opening and is capable of being patterned, the first surfactant (II) is preferably a surfactant that exhibits lipophilicity, further preferably a fluorine-free surfactant, more preferably a fluorine-free nonionic surfactant, anionic surfactant or amphoteric surfactant, or mixtures thereof.

In a preferred embodiment of the present invention, from the viewpoint of providing a composition that can create a bank that exhibits lipophilicity more effectively with respect to QD ink at least at the bottom of the bank or the bottom of the bank and the bank side of the opening, it is preferable that the first surfactant (II) is a fluorine-free nonionic surfactant, more preferably the first surfactant (II) is polyoxyethylene alkyl ethers such as polyoxyethylene lauryl ether, polyoxyethylene oleyl ether and polyoxyethylene cetyl ether, polyoxyethylene fatty acid diesters, polyoxyethylene fatty acid monoesters, polyoxyethylene polyoxypyropyrene block polymer, acetylene alcohols, acetylene glycols, polyethoxylates of acetylene alcohol, acetylene glycol derivatives such as polyethoxylates of acetylene glycol, organosiloxane surfactants, silicon-based surfactants, or mixtures thereof. The surfactant that exhibits lipophilicity, such as a fluorine-free surfactant, can be suitably selected from known and available materials. As such known and available materials, silicon-based surfactants manufactured by DIC Corporation, SOILNON AF-800 (Nicca Chemical), Glide ZG400 (Evonik Industries), AKS-10 (Shin-Etsu Chemical), and the like can be suitably used.

Preferably, in the present invention, “bank” means a partition wall or a black matrix that is arranged between display pixels of an optical display device and divides the display pixels and means, for example, banks and black matrices as described in JP-A 2021-075660, WO2017-138607A1, and JP-A 2018-203599.

### (III) Second Surfactant

The composition according to the present invention comprises a second surfactant (III). In the present invention, the second surfactant (III) is not particularly limited as long as it achieves at least one or more of the effects of the present invention, but from the viewpoint of providing a composition that exhibits oil repellency at the upper part of the formed film, and preferably a patternable composition that exhibits oil repellency at the top of the bank, the second surfactant (III) is preferably a surfactant that exhibits oil repellency, more preferably a fluorosurfactant or a fluorine-containing surfactant, and from the viewpoint of better oil repellency, a fluorine-containing surfactant is further preferable. Furthermore, preferred is a fluorine-containing nonionic surfactant, anionic surfactant or amphoteric surfactant, or mixtures thereof. The surfactant that exhibits oil repellency, such as a fluorine-containing surfactant, can be suitably selected from known and available materials. As such known and available materials, fluorine-containing surfactants manufactured by Daikin Industries, Ltd. and Surflon (AGC Seimi Chemical Co., Ltd.), which is a surfactant having a perfluoroalkyl group, and the like can be suitably used.

In a preferred embodiment of the present invention, from the viewpoint of providing a composition capable of forming a bank that exhibits oil repellency more effectively to QD ink at the top of the bank, the second surfactant (III) is preferably a fluorine-containing nonionic surfactant.

Although not to be bound by theory, from the viewpoint of providing a composition capable of forming a bank that exhibits oil repellency more effectively with respect to QD ink at the top of the bank, preferably the molecular weight of the second surfactant (III) may be lower than that of the first surfactant (II) or the alkali-soluble polymer (I).

### (II) First Surfactant and (III) Second Surfactant

In the present invention, the composition according to the present invention comprises a first surfactant (II) and a second surfactant (III), wherein the first surfactant (II) and the second surfactant (III) are not particularly limited as long as they achieve at least one or more of the effects of the present invention, but it is characterized in that from the viewpoint of providing a patternable composition that exhibits lipophilicity at least at the bottom of the bank or the bottom of the bank and bank side of the opening and exhibits oil repellency at the top portion of the bank, the first surfactant (II) is preferably a fluorine-free surfactant, preferably a fluorine-free nonionic surfactant, anionic surfactant or amphoteric surfactant, or mixtures thereof, the second surfactant (III) is a fluorine-containing surfactant, preferably a fluorine-containing nonionic surfactant, anionic surfactant, amphoteric surfactant or a mixture thereof.

Although not to be bound by theory, it can be thought that using a combination of the second surfactant that exhibits oil repellency and the first surfactant that exhibits lipophilicity, after coating or baking the composition, a distribution of surfactant occurs in the film thickness direction, and as a result, the second surfactant that exhibits oil repellency is largely distributed near the film surface, and relatively, the first surfactant that exhibits lipophilicity is largely distributed other than in the vicinity of the film surface, for example, in the vicinity of the film substrate.

By exposing, developing and curing this film as desired, it can be thought that oil repellency reveals at the upper part (the top of the bank when the bank is formed) and lipophilicity reveals at the lower part (the bottom of the bank when the bank is formed).

In a preferred embodiment, from the viewpoint of providing a composition capable of forming a bank that exhibits lipophilicity more effectively with respect to the QD ink at least at the bottom of the bank or the bottom of the bank and the bank side of the opening and exhibits oil repellency more effectively with respect to the QD ink at the top of the bank, it is preferable that the first surfactant (II) is a fluorine-free nonionic surfactant, more preferably the first surfactant (II) is polyoxyethylene alkyl ethers such as polyoxyethylene lauryl ether, polyoxyethylene oleyl ether and polyoxyethylene cetyl ether, polyoxyethylene fatty acid diesters, polyoxyethylene fatty acid monoesters, polyoxyethylene polyoxypyropyrene block polymer, acetylene alcohols, acetylene glycols, polyethoxylates of acetylene alcohol, acetylene glycol derivatives such as polyethoxylates of acetylene glycol, organosiloxane surfactants, silicon-based surfactants, or mixtures thereof.

Preferably, the second surfactant (III) is a fluorine-containing nonionic surfactant.

In a preferred embodiment of the present invention, from the viewpoint of providing a composition capable of forming a bank that exhibits lipophilicity more effectively with respect to the QD ink at the bottom of the bank or the bottom of the bank and the bank side of the opening and exhibits oil repellency more effectively with respect to the QD ink at the top of the bank, it is preferable that the mass ratio of the first surfactant (II) to the second surfactant (III) (the first surfactant (II):the second surfactant (III)) is 1:1,000 to 99:10, more preferably 1:100 to 5:1, further preferably 1:50 to 2:1, most preferably 1:20 to 1:1. Within the above range, it becomes possible to provide a composition capable of forming a bank that exhibits lipophilicity more effectively with respect to the QD ink at the bottom of the bank or the bottom of the bank and the bank side of the opening and exhibits oil repellency more effectively with respect to the QD ink at the top of the bank.

In a preferred embodiment of the present invention, from the viewpoint of providing a composition capable of forming a bank that exhibits more effective lipophilicity with respect to the QD ink at the bottom of the bank or the bottom of the bank and the bank side of the opening and exhibits oil repellency more effectively with respect to the QD ink at the top of the bank, the content of the first surfactant (II) is in the range of preferably 0.001 to 5 mass %, more preferably 0.01 to 1 mass %, further preferably 0.02 to 0.5 mass %, most preferably 0.03 to 0.3 mass %, based on the total mass of the alkali-soluble material. The content of the second surfactant (III) is in the range of preferably 0.05 to 10 mass %, more preferably 0.1 to 5 mass %, further preferably 0.2 to 1 mass %, most preferably 0.3 to 0.5 mass %, based on the total mass of the alkali-soluble material.

In the present invention, the average film thickness is obtained by measuring a film thickness at 3 to 5 points with a stylus type surface profilometer manufactured by ULBAC, Inc. and taking the average value thereof.

The viscosity of the composition according to the present invention is preferably 0.1 to 10,000 cP, more preferably 1.0 to 8,000 cP. The viscosity is measured at 25° C. with a rotational viscometer.

### (IV) Coloring Agent

The composition according to the present invention can comprise a coloring agent (IV). Preferably, the coloring agent (IV) is an organic coloring agent and/or an inorganic coloring agent, more preferably an organic and/or inorganic black coloring agent, further preferably an organic black coloring agent, and further more preferably the coloring agent is a black coloring agent consisting of a mixture of two or more organic coloring agents, and further more preferably the coloring agent (IV) is a mixture of red and blue-green organic coloring agents mixed to give a black color.

When the black coloring agent used in the present invention is an organic coloring agent or pigment, it is preferable to combine two or more organic coloring agents or pigments. A black color material can be obtained by mixing each color of red, green, blue, etc.

The organic coloring agent and pigment are selected from those having a structure of azo-based, phthalocyanine-based, quinacridone-based, benzimidazolone-based, isoindolinone-based, dioxazine-based, indanthrene-based, perylene-based, etc. Preferred pigment combination includes, for example, a combination of one or more selected from the group consisting of C.I. Pigment Orange 43, C.I. Pigment Orange 64 and C.I. Pigment Orange 72, with one or more selected from the group consisting of C.I. Pigment Blue 60, C.I. Pigment Green 7, C.I. Pigment Green 36 and C.I. Pigment Green 58, more preferably a combination of one selected from the group consisting of C.I. Pigment Orange 43, C.I. Pigment Orange 64 and C.I. Pigment Orange 72, with C.I. Pigment Blue 60. This combination may be further combined with other organic pigments.

The content of the coloring agent (IV) is preferably 3 to 80 mass %, more preferably 5 to 50 mass %, based on the total mass of the alkali-soluble material.

The content of the coloring agent is based on the mass of the pigment itself. In other words, there is also a case where the coloring agent is obtained in a dispersed state using a dispersant, but in this case, anything other than the pigment is not included in the mass of the coloring agent.

The coloring agent used in the present invention can also be used in combination with a dispersant. As the dispersant, for example, an organic compound-based dispersant such as a polymer dispersant described in JP 2004-292672 A may be used.

### (V) Polymerization Initiator

The composition according to the present invention can comprise a polymerization initiator. This polymerization initiator includes a polymerization initiator that generates an acid, base or radical by radiation and a polymerization initiator that generates an acid, base or radical by heat. In the present invention, since the reaction starts immediately after the radiation irradiation, and the reheating step that is performed after the radiation irradiation and before the development step can be omitted, the former is preferred in terms of process shortening and cost, and photoradical generators are more preferred.

The photoradical generator can improve the resolution by strengthening the pattern shape and increasing the development contrast. The photoradical generator used in the present invention is a photoradical generator that releases radicals when irradiated with radiation. Examples of radiation include visible light, ultraviolet ray, infrared ray, X-ray, electron beam, α-ray, or γ-ray.

The optimum amount of the photoradical generator to be added varies depending on the type of the active substance generated by decomposition of the photoradical generator, the amount generated thereof, the required sensitivity, and the dissolution contrast between the exposed area and unexposed area, but it is preferably 0.001 to 50 mass %, more preferably 0.01 to 30 mass %, based on the total mass of the alkali-soluble polymer. If the amount added is less than 0.001 mass %, the dissolution contrast between the exposed area and the unexposed area is too low, the addition effect may not be obtained. On the other hand, if the amount of the photoradical generator added is more than 50 mass %, cracks may occur in the formed film, and coloration due to decomposition of the photoradical generator may become remarkable, which may reduce the colorless transparency of the coating film. Further, if the amount added is too large, thermal decomposition of the photoradical generator may cause deterioration of the electrical insulation properties of the cured product and release of gas, which may cause problems in a subsequent process. Furthermore, the resistance of the coating film to a photoresist stripper containing monoethanolamine or the like as a main ingredient may be lowered.

Examples of the photoradical generator include azo-based, peroxide-based, acylphosphine oxide-based, alkylphenone-based, oxime ester-based, and titanocene-based initiators. Among them, alkylphenone-based, acylphosphine oxide-based and oxime ester-based initiators are preferable, and examples thereof include 2,2-dimethoxy-1,2-diphenyl-ethan-1-one, 1-hydroxycyclohexylphenyl ketone, 2-hydroxy-2-methyl-1-phenylpropan-1-one, 1-[4-(2-hydroxyethoxy)phenyl]-2-hydroxy-2-methyl-1-propan-1-one, 2-hydroxy-1-{4-[4-(2-hydroxy-2-methyl-propionyl)benzyl]phenyl}-2-methylpropan-1-one, 2-methyl-1-(4-methylthiophenyl)-2-morpholinopropan-1-one, 2-benzyl-2-dimethylamino-1-(4-morpholino-phenyl)-1-butanone, 2-(dimethylamino)-2-[(4-methyl-phenyl)methyl]-1-[4-(4-morpholinyl)phenyl]-1-butanone, 2,4,6-trimethylbenzoyldiphenylphosphine oxide, bis(2,4,6-trimethylbenzoyl)phenylphosphine oxide, 1,2-octanedione, 1-[4-(phenylthio)-2-(O-benzoyloxime)], ethanone, 1-[9-ethyl-6-(2-methylbenzoyl)-9H-carbazol-3-yl]-1-(O-acetyloxime), etc.

### (VI) Solvent

The composition according to the present invention can comprise a solvent. The solvent is not particularly limited as long as it uniformly dissolves or disperses the alkali-soluble material, surfactant, and optionally added components. Examples of the solvent that can be used in the present invention include ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether and propylene glycol monoethyl ether; propylene glycol alkyl ether acetates, such as PGMEA, propylene glycol monoethyl ether acetate and propylene glycol monopropyl ether acetate; aromatic hydrocarbons, such as benzene, toluene and xylene; ketones, such as methyl ethyl ketone, acetone, methyl amyl ketone, methyl isobutyl ketone and cyclohexanone; alcohols, such as ethanol, propanol, butanol, hexanol, cyclohexanol, ethylene glycol and glycerin; esters, such as ethyl lactate, ethyl 3-ethoxypropionate and methyl 3-methoxypropionate; cyclic esters, such as γ-butyrolactone. Among these, propylene glycol alkyl ether acetates or esters, and alcohols having linear or branched alkyl groups with 4 or 5 carbon atoms are preferably used from the viewpoint of availability, ease of handling, solubility of alkali-soluble materials, etc. From the viewpoint of coatability, storage stability and the like, the solvent ratio of the alcohol is preferably 5 to 80%.

The solvent content of the composition according to the present invention can be freely adjusted according to the method of applying the composition and the like. For example, when the composition is applied by spray coating, the proportion of the solvent in the composition may be 90 mass % or more. In a case of slit coating, which is used for coating large substrates, it is usually 60 mass % or more, preferably 70 mass % or more. The properties of the compositions of the present invention do not vary greatly with the amount of solvent.

### (VII) Additive

The composition according to the present invention may, if necessary, comprise an additive (VII) other than the components described above. Such an additive is at least one of a developer dissolution accelerator, a scum remover, an adhesion enhancer, a polymerization inhibitor, an antifoaming agent, a third surfactant different from the first and second surfactants, a sensitizer, a crosslinker, a hardener, or a mixture thereof. As the developer dissolution accelerator, for example, 4-hydroxybutyl acrylate and the like can be suitably used.

The content of the additive (VII) is preferably 5 mass % or less, more preferably 1 mass % or less. In a preferred embodiment, the additive (VII) is not contained in the composition, that is, the content thereof is 0 mass %.

The scum remover is one that adjusts the solubility of the formed coating film in the developer, and also has a function to prevent scum from remaining on the substrate after development. A crown ether can be used as such an additive. One having the simplest structure as the crown ether is represented by the general formula (—CH₂—CH₂—O—)ₙ. Among these, those in which n is 4 to 7 are preferred in the present invention.

The crown ether is sometimes called x-crown-y-ether, where x is the total number of atoms composing the ring and y is the number of oxygen atoms contained therein. In the present invention, those selected from the group consisting of crown ethers where x=12, 15, 18 or 21 and y=x/3, and their benzo condensates and cyclohexyl condensates are preferred. Exemplified embodiments of more preferred crown ether are 21-crown-7-ether, 18-crown-6-ether, 15-crown-5-ether, 12-crown-4-ether, dibenzo-21-crown-7-ether, dibenzo-18-crown-6-ether, dibenzo-15-crown-5-ether, dibenzo-12-crown-4-ether, dicyclohexyl-21-crown-7-ether, dicyclohexyl-18-crown-6-ether, dicyclohexyl-15-crown-5-ether, and dicyclo-hexyl-12-crown-4-ether. In the present invention, among these, those selected from 18-crown-6-ether and 15-crown-5-ether are most preferred. Its content is preferably 0.05 to 15 mass %, more preferably 0.1 to 10 mass %, based on the total mass of the alkali-soluble material.

The adhesion enhancer has an effect of preventing peeling of the pattern due to stress applied after baking when a cured film is formed using the composition according to the present invention. As the adhesion enhancer, imidazoles, silane coupling agents, and the like are preferable. Among imidazoles, 2-hydroxybenzimidazole, 2-hydroxyethylbenzimidazole, benzimidazole, 2-hydroxyimidazole, imidazole, 2-mercaptoimidazole, 2-aminoimidazole are preferred, and 2-hydroxybenzimidazole, benzimidazole, 2-hydroxyimidazole and imidazole are in particular preferably used.

As the silane coupling agent, ones known are suitably used, and examples thereof include epoxysilane coupling agents, aminosilane coupling agents, mercaptosilane coupling agents, and the like. In particular, 3-glycidoxypropyltrimethoxysilane, 3-glycidoxypropyltriethoxysilane, N-2-(aminoethyl)-3-aminopropyltrimethoxysilane, N-2-(aminoethyl)-3-aminopropyltriethoxysilane, 3-aminopropyltrimethoxysilane, 3-aminopropyltriethoxysilane, 3-ureidopropyltriethoxysilane, 3-chloropropyltriethoxysilane, 3-mercaptopropyltrimethoxysilane, 3-isocyanatopropyltriethoxysilane, and the like are preferred. These can be used alone or in combination of a plurality of any of them, and the amount added is preferably 0.05 to 15 mass % based on the total mass of the alkali-soluble material.

A silane compound having an acid group, a siloxane compound, or the like can also be used as the silane coupling agent. Examples of the acid group include a carboxy group, an acid anhydride group, a phenolic hydroxyl group, and the like. When it contains a monobasic acid group such as a carboxyl group or a phenolic hydroxyl group, it is preferred that a single silicon-containing compound has a plurality of acid groups.

An exemplified embodiment of such a silane coupling agent includes a compound represented by the formula (C):

XₙSi(OR³)₄₋ₙ (C)
or a polymer having it as a polymer unit. At this time, a plurality of polymerized units having different X or R³ can be used in combination.

In the formula, R³ includes hydrocarbon groups such as alkyl groups, for example, methyl group, ethyl group, n-propyl group, isopropyl group, n-butyl group, and the like. In the general formula (C), a plurality of R³ is included, and each R³ may be the same or different.

Examples of X includes: those having an acid group such as phosphonium, borate, carboxy, phenol, peroxide, nitro, cyano, sulfo and alcohol group; as well as those in which these acid groups are protected by acetyl, aryl, amyl, benzyl, methoxymethyl, mesyl, tolyl, trimethoxysilyl, triethoxysilyl, triisopropylsilyl, trityl group, or the like; and acid anhydride group.

Among these, one having a methyl group as R³ and a carboxylic acid anhydride group as X, for example, acid anhydride group-containing silicone, is preferred. More particularly, a compound represented by the following formula (X-12-967C (trade name, Shin-Etsu Chemical Co., Ltd.)) or polymer containing a structure corresponding thereto in the terminal or side chain of a silicon-containing polymer such as silicone is preferred.

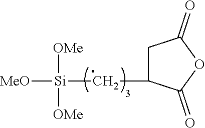

A compound obtained by imparting an acid group such as thiol, phosphonium, borate, carboxy, phenol, peroxide, nitro, cyano, and sulfo groups to the ends of dimethyl silicone is also preferred. Such a compound includes the compounds represented by the following formulae (X-22-2290AS and X-22-1821 (both are trade names, Shin-Etsu Chemical Co., Ltd.)).

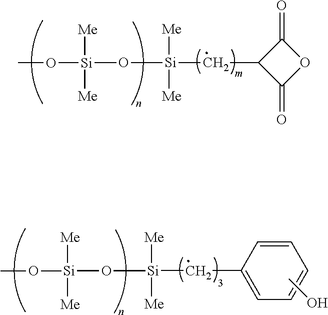

When the silane coupling agent contains a silicone structure, if the molecular weight is too large, there is a possibility of adverse effects, such as the compatibility with the polysiloxane contained in the composition is poor, the solubility in the developer is not improved, reactive groups remain in the film, and the inability to maintain chemical resistance to withstand in a subsequent process, may occur. For this reason, the mass average molecular weight of the silane coupling agent is preferably 5,000 or less, more preferably 4,000 or less. The content of the silane coupling agent is preferably 0.01 to 15 mass % based on the total mass of the alkali-soluble polymer.

As the polymerization inhibitor, nitrone, nitroxide radical, hydroquinone, catechol, phenothiazine, phenoxazines, hindered amine and their derivatives, as well as UV absorber can be added. Among them, methylhydroquinone, catechol, 4-t-butylcatechol, 3-methoxycatechol, phenothiazine, chlorpromazine, phenoxazine, TINUVIN 144, 292, 5100 (BASF) as the hindered amine, TINUVIN 326, 328, 384-2, 400, 477 (BASF) as the UV absorber, are preferred. These can be used alone or in combination of a plurality of any of them, and their content is preferably 0.01 to 20 mass % based on the total mass of the alkali-soluble material.

As the antifoaming agent, alcohols (C₁₋₁₈), higher fatty acids such as oleic acid and stearic acid, higher fatty acid esters such as glycerin monolaurate, polyethers such as polyethylene glycol (PEG) (Mn 200 to 10,000) and polypropylene glycol (PPG) (Mn 200 to 10,000), silicone compounds such as dimethyl silicone oil, alkyl-modified silicone oil and fluorosilicone oil, organic siloxane-based surfactants detailed below, and the like are included. These can be used alone or in combination of a plurality of any of them, and their content is preferably 0.1 to 3 mass % based on the total mass of the alkali-soluble material.

A sensitizer can be added to the composition according to the present invention, if necessary.

The sensitizer preferably used in the composition according to the present invention include coumarin, ketocoumarin and derivatives thereof, thiopyrylium salts, acetophenones, etc. In particular, p-bis(o-methyl-styryl)benzene, 7-dimethylamino-4-methylquinolone-2,7-amino-4-methylcoumarin, 4,6-dimethyl-7-ethyl-aminocoumarin, 2-(p-dimethylaminostyryl)-pyridyl-methyl iodide, 7-diethylaminocoumarin, 7-diethylamino-4-methylcoumarin, 2,3,5,6-1H,4H-tetrahydro-8-methyl-quinolidino-<9,9a, 1-gh>coumarin, 7-diethylamino-4-trifluoromethylcoumarin, 7-dimethylamino-4-trifluoromethylcoumarin, 7-amino-4-trifluoromethylcoumarin, 2,3,5,6-1H,4H-tetrahydroquinolidino-<9,9a,1-gh>-coumarin, 7-ethylamino-6-methyl-4-trifluoromethylcoumarin, 7-ethylamino-4-trifluoromethylcoumarin, 2,3,5,6-1H,4H-tetrahydro-9-carboethoxyquinolidino-<9,9a,1-gh>coumarin, 3-(2′-N-methylbenzimidazolyl)-7-N,N-diethylaminocoumarin, N-methyl-4-trifluoro-methylpiperidino-<3,2-g>coumarin, 2-(p-dimethyl-aminostyryl)-benzothiazolylethyl iodide, 3-(2′-benz-imidazolyl)-7-N, N-diethylaminocoumarin and 3-(2′-benzothiazolyl)-7-N, N-diethylaminocoumarin, as well as sensitizing dyes such as pyrylium salts and thiopyrylium salts represented by the following chemical formulae are included. Addition of a sensitizing dye enables patterning using an inexpensive light source such as a high-pressure mercury lamp (360 to 430 nm). Its content is preferably 0.05 to 15 mass %, more preferably 0.1 to 10 mass %, based on the total mass of the alkali-soluble material.

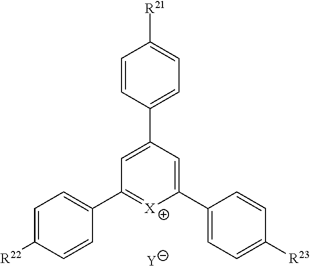

| X | R²¹ | R²² | R²³ | Y |
|---|---|---|---|---|
| S | OC₄H₉ | H | H | BF₄ |
| S | OC₄H₉ | OCH₃ | OCH₃ | BF₄ |
| S | H | OCH₃ | OCH₃ | BF₄ |
| S | N(CH₃)₂ | H | H | ClO₂ |
| O | OC₄H₉ | H | H | SbF₆ |

A compound containing an anthracene skeleton can also be used as a sensitizer. In particular, compounds represented by the following formula can be included.

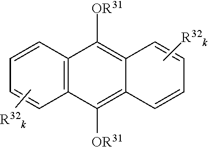

wherein,
R³¹ each independently represents a substituent selected from the group consisting of an alkyl group, an aralkyl group, an allyl group, a hydroxyalkyl group, an alkoxyalkyl group, a glycidyl group and a halogenated alkyl group;
R³² each independently represents a substituent selected from the group consisting of a hydrogen atom, an alkyl group, an alkoxy group, a halogen atom, a nitro group, a sulfonic acid group, a hydroxyl group, an amino group and a carboalkoxy group; and
k is each independently an integer selected from 0, and 1 to 4.

When using such a sensitizer having an anthracene skeleton, its content is preferably 0.01 to 5 mass % based on the total mass of the alkali-soluble polymer.

A crosslinker can be added to the composition according to the present invention, if necessary. Examples of the crosslinker include melamine compounds having a methylol group, alkoxymethyl group, etc., isocyanate compounds, and the like.

If a melamine compound is exemplified among the examples of the crosslinker, NIKALAC MW-390, NIKALAC MW-100 LM, NIKALAC MX-750 LM, NIKALAC MX-270, NIKALAC MX-280, etc. having an imino group, a methylol group, a methoxymethyl group, and the like are mentioned.

As the isocyanate compound, X-12-9659 or KBM-9659, X-12-9659 or KBM-585 (Shin-Etsu Chemical Co., Ltd.) are mentioned.

Polymer containing these structures, or polymer in which a part of these structures are replaced with silicone groups are also preferred. In addition to the silane compound, Karenz AOI, Karenz MOI-BM, Karenz MOI-BP, Karenz BEI, Karenz MT (Showa Denko K.K.), hexamethylene diisocyanate, cyclohexane diisocyanate, and the like are mentioned.

The content of the crosslinker is preferably 1 to 80 mass %, more preferably 5 to 50 mass %, further preferably 10 to 30 mass %, based on the total mass of the alkali-soluble material. It can be used alone or in combination of two or more.

### <Method for Forming Cured Film>

The method for forming a cured film according to the present invention comprises a step of applying the above-mentioned composition above a substrate to form a coating film, and a step of heating the coating film. In the present invention, the “above a substrate” includes the case where the composition is applied directly on a substrate and the case where the composition is applied on a substrate via one or more intermediate layer.

Preferably, the method for manufacturing a cured film further comprises a step of exposing the coating film to light and a step of developing the coating film. More preferably, the method for manufacturing a cured film according to the present invention comprises a step of applying the above-mentioned composition above a substrate to form a coating film, a step of exposing the coating film to light, a step of developing the coating film, and a step of heating in this order, and further preferably comprises a step of prebaking after the step of applying and before the step of exposing.

The method for forming a cured film of the present invention is described below in order of steps.

### (1) Step of Applying

First, the composition described above is applied above a substrate. Formation of a coating film of the composition in the present invention can be performed by any method conventionally known as a method for applying a photosensitive composition. In particular, it can be freely selected from dip coating, roll coating, bar coating, brush coating, spray coating, doctor coating, flow coating, spin coating, slit coating, and the like. As the substrate for applying the composition, any suitable substrate such as silicon substrate, glass substrate and resin film can be used. Various semiconductor elements and the like may be formed on these substrates as required. When the substrate is a film, gravure coating is also available. If desired, a step of drying can be separately provided after applying. The step of applying can be repeated once or twice or more as necessary to obtain a desired film thickness of the formed coating film.

### (2) Step of Prebaking

After forming a coating film by applying the composition, it is preferable to perform prebaking (preheating treatment) the coating film in order to dry the coating film and reduce the amount of solvent remaining in the coating film. The step of prebaking can be generally performed at a temperature of 40 to 150° C., preferably 50 to 100° C., and for 10 to 300 seconds, preferably 30 to 120 seconds when using a hot plate and for 1 to 30 minutes when using a clean oven.

### (3) Step of Exposing

After the coating film is formed, the surface of the coating film is irradiated with light as desired. Any light source conventionally used in the pattern forming method can be used for the light irradiation. Examples of such a light source include lamps such as high-pressure mercury lamp, low pressure mercury lamp, metal halide lamp and xenon lamp, laser diode, and LED. Ultraviolet rays such as g-line, h-line and i-line are usually used as irradiation light. Except for ultrafine processing such as semiconductors, light of 360 to 430 nm (high pressure mercury lamp) is generally used for patterning of several μm to several ten μm. The energy of the irradiation light is generally 5 to 2,000 mJ/cm², preferably 10 to 1,000 mJ/cm², although it depends on the light source and the film thickness of the coating film. If the irradiation light energy is lower than 10 mJ/cm², sufficient resolution may not be obtained, and conversely, if it is higher than 2,000 mJ/cm², the exposure is excessive and halation may occur.

In order to irradiate light in a pattern shape, a general photomask can be used. Such a photomask can be freely selected from well-known ones. The environment for irradiation is not particularly limited, but generally the surrounding atmosphere (in the atmosphere) or nitrogen atmosphere may be accessible. Further, when a film is formed on the entire surface of the substrate, the entire surface of the substrate can be irradiated with light. In the present invention, “patterned film” also includes the case where such a film is formed on the entire surface of the substrate.

### (4) Step of Post Exposure Baking

After exposure, post exposure baking can be performed, as necessary, in order to promote the reaction between polymer in the film by the reaction initiator generated at the exposed area. Unlike the step of heating (6) described later, this heat treatment is not performed to completely cure the coating film, but it is performed to make it possible to remain the desired pattern on the substrate after development and to remove the other portion by development. Therefore, this is not essential in the present invention.

When performing the post exposure baking, a hot plate, oven or furnace can be used. The heating temperature should not be excessively high, because it is undesirable for the acid in the exposed area, which is generated by the light irradiation, to diffuse into the unexposed area. From such a viewpoint, the range of the heating temperature after exposure is preferably 40° C. to 150° C., more preferably 60° C. to 120° C. Stepwise heating can also be applied, if desired, to control the curing rate of the composition. The atmosphere during heating is not particularly limited, but for the purpose of controlling the curing speed of the composition, it can be selected from in an inert gas such as nitrogen, in a vacuum, under reduced pressure, in oxygen gas, and the like. Moreover, the heating time is preferably at least a certain level in order to maintain the uniformity of the temperature history within the wafer surface, and is preferably not excessively long in order to suppress the diffusion of the generated acid. From this point of view, the heating time is preferably 20 seconds to 500 seconds, more preferably 40 seconds to 300 seconds.

### (5) Step of Developing

After exposure, the post exposure baking is performed as necessary, and then the coating film is subjected to treatment of developing. As a developer used for development, any developer that is conventionally used for developing photosensitive compositions can be used. Preferred developers include an alkaline developer that is an aqueous solution of an alkaline compound such as tetraalkylammonium hydroxide, choline, alkali metal hydroxide, alkali metal metasilicate (hydrate), alkali metal phosphate (hydrate), sodium carbonate aqueous solution, ammonia, alkylamine, alkanolamine and heterocyclic amine, and particularly preferable alkaline developer is tetramethylammonium hydroxide aqueous solution, potassium hydroxide aqueous solution, sodium hydroxide aqueous solution, and sodium carbonate aqueous solution. These alkaline developers may further contain, if necessary, a water-soluble organic solvent such as methanol and ethanol, or a surfactant. In the present invention, development can be performed using a developer having a lower concentration than that of the 2.38 mass % TMAH developer that is usually used as a developer. Such a developer includes, for example, a 0.05 to 1.5 mass % TMAH aqueous solution, a 0.1 to 2.5 mass % sodium carbonate aqueous solution, a 0.01 to 1.5 mass % potassium hydroxide aqueous solution, and the like. The development time is usually 10 to 300 seconds, preferably 30 to 180 seconds.

The development method can also be freely selected from conventionally known methods. In particular, methods such as immersion (dip) in a developer, paddle, shower, slit, cap coat, and spray are mentioned. A pattern can be obtained by this development, and it is preferable to rinse with water after development with a developer.

### (6) Step of Heating

The coating film is cured by heating. As the heating device to be used in the step of heating, the same device as used in the above-mentioned post exposure baking can be used. The heating temperature in this step of heating is not particularly limited as long as it is a temperature at which the coating film can be cured, and can be freely determined. However, when a polysiloxane is used, if silanol groups remain in the polysiloxane, the chemical resistance of the cured film may become insufficient, or the dielectric constant of the cured film may increase. From such a point of view, a relatively high temperature is generally selected as the heating temperature. However, the composition according to the invention is capable of curing at a relatively low temperature. In particular, it is preferable to cure by heating at 350° C. or lower, and in order to keep the residual film rate after curing high, the curing temperature is more preferably 300° C. or lower, in particular preferably 250° C. or lower. On the other hand, in order to accelerate the curing reaction and to obtain a sufficient cured film, the curing temperature is preferably 70° C. or higher, more preferably 80° C. or higher. Further, the heating time is not particularly limited, and is generally 10 minutes to 24 hours, preferably 20 minutes to 3 hours. This heating time is the time from when the temperature of the patterned film reaches the desired heating temperature. It usually takes several minutes to several hours for the patterned film to reach the desired temperature from the temperature before heating.

The cured film thus formed exhibits the effects of the present application if the film has an average film thickness of 100 μm or less, and the film preferably has a thickness of 5 to 100 μm. It is more preferably 5 to 25 μm, further preferably 8 to 20 μm. As to the optical density (OD) of the cured film, average thereof is preferably 1.5 or more, more preferably 2 or more at a wavelength of 400 to 700 nm. The optical density is measured by Spectrophotometer CM-5 (Konica Minolta). The cured film according to the present invention has good light-shielding properties and can be used as a partition wall material for display devices. Since the cured film according to the present invention can be made thicker, it can be suitably used for quantum dots and organic electroluminescence devices that require a thicker partition wall material.

In another aspect, the present invention relates to a cured film manufactured or capable of being manufactured by the above method.

In another aspect, the present invention relates to a cured film comprising:
a polymer (A) derived from an alkali-soluble material,
a first surfactant; and
a second surfactant different from the first surfactant.

Preferably, this cured film is preferably patterned, more preferably a patterned bank.

Preferably, the polymer (A) has a network crosslinked structure, and is more preferably a polymer derived from the alkali-soluble material (I) and the polymerization initiator (V) described above.

Preferably, the cured film further comprises a coloring agent. More preferably, the coloring agent is an organic coloring agent and/or an inorganic coloring agent, further preferably the coloring agent is an organic and/or inorganic black coloring agent.

In another aspect, the present invention relates to a light conversion device comprising the cured film.

In another aspect, the present invention relates to a display device comprising the cured film or the light conversion device.

Preferred embodiments are listed below.

### Embodiment 1

A composition, comprising
(I) an alkali-soluble material;
(II) a first surfactant; and
(III) a second surfactant different from the first surfactant,
or consisting essentially of the above-mentioned alkali-soluble material (I), first surfactant (II), and second surfactant (III) different from the first surfactant, or consisting of the above-mentioned alkali-soluble material (I), first surfactant (II), and second surfactant (III) different from the first surfactant.

Preferably, the composition is a cured film-forming composition.

Preferably, the composition is a photosensitive composition. More preferably, the composition is a negative type photosensitive composition.

Preferably, the composition further comprises (IV) a coloring agent, which is preferably an organic coloring agent and/or an inorganic coloring agent, more preferably an organic and/or inorganic black coloring agent;
(V) a polymerization initiator; and/or
(VI) a solvent.

Preferably, the alkali-soluble material (I) has a structural portion having an acid group. The acid group is preferably one that has an acid dissociation index (pKa) of 7 or less, more preferably —OH, —COOH, —SO₃H, —OSO₃H, —PO₃H₂, —OPO₃H₂, —CONHSO₂ and —SO₂NHSO₂—, further preferably —COOH.

### Embodiment 2

The composition according to Embodiment 1, wherein
the first surfactant (II) is a surfactant that exhibits lipophilicity, preferably a fluorine-free surfactant, more preferably a fluorine-free nonionic surfactant, anionic surfactant or amphoteric surfactant, or a mixture thereof; and
the second surfactant (III) is a surfactant that exhibits oil repellency, preferably a fluorosurfactant or fluorine-containing surfactant that exhibits oil repellency, more preferably a fluorine-containing surfactant, further preferably a fluorine-containing nonionic surfactant, fluorine-containing anionic surfactant, fluorine-containing amphoteric surfactant or a mixture thereof.

Preferably, the first surfactant (II) is a fluorine-free nonionic surfactant, more preferably the first surfactant (II) is polyoxyethylene alkyl ethers such as polyoxyethylene lauryl ether, polyoxyethylene oleyl ether and polyoxyethylene cetyl ether, polyoxyethylene fatty acid diesters, polyoxyethylene fatty acid monoesters, polyoxyethylene polyoxypyropyrene block polymer, acetylene alcohols, acetylene glycols, polyethoxylates of acetylene alcohol, acetylene glycol derivatives such as polyethoxylates of acetylene glycol, organosiloxane surfactants, silicon-based surfactants, or mixtures thereof.

Preferably the second surfactant (III) is a fluorine-containing nonionic surfactant.

### Embodiment 3

The composition according to Embodiment 1 or 2, wherein,
the mass ratio of the first surfactant (II) to the second surfactant (III) (the first surfactant (II):the second surfactant (III)) is 1:1,000 to 99:10, more preferably 1:100 to 5:1, further preferably 1:50 to 2:1, most preferably 1:20 to 1:1.

### Embodiment 4

The composition according to any one of Embodiments 1 to 3,
wherein,
the content of the first surfactant (II) is preferably 0.001 to 5 mass %, more preferably 0.01 to 1 mass %, further preferably 0.02 to 0.5 mass %, most preferably 0.03 to 0.3 mass %, based on the total mass of the alkali-soluble material, and the content of the second surfactant (III) is preferably 0.05 to 10 mass %, more preferably 0.1 to 5 mass %, further preferably 0.2 to 1 mass %, most preferably 0.3 to 0.5 mass %, based on the total mass of the alkali-soluble material.

### Embodiment 5

The composition according to any one of Embodiments 1 to 4, further comprising a coloring agent (IV). Preferably, the coloring agent (IV) is an organic and/or inorganic black coloring agent, more preferably an organic black coloring agent, and further preferably a black coloring agent consisting of a mixture of two or more organic coloring agents, and further more preferably a mixture of red and blue-green organic coloring agents mixed to give a black color. Further preferably, the coloring agent (IV) is a black coloring agent consisting of a mixture of organic coloring agents selected from the group consisting of azo-based, phthalocyanine-based, quinacridone-based, benzimidazolone-based, isoindolinone-based, dioxazine-based, indanthrene-based and perylene-based, and most preferably the organic black coloring agent is a combination of one or more selected from the group consisting of C.I. Pigment Orange 43, C.I. Pigment Orange 64 and C.I. Pigment Orange 72, with one or more selected from the group consisting of C.I. Pigment Blue 60, C.I. Pigment Green 7, C.I. Pigment Green 36 and C.I. Pigment Green 58.

Preferably, the content of the coloring agent (IV) is 3 to 80 mass %, more preferably 5 to 50 mass %, based on the total mass of the alkali-soluble material.

### Embodiment 6

The composition according to any one of Embodiments 1 to 5, wherein the alkali-soluble material (I) is a compound containing two or more (meth)acryloyloxy groups and/or an alkali-soluble polymer.

Preferably, the compound containing two or more (meth)acryloyloxy groups is esters obtained by reacting (α)ₐ polyol compound having two or more hydroxyl groups and (β) two or more (meth)acrylic acids.

Preferably, the polyol compound (α) is a compound that has a saturated or unsaturated aliphatic hydrocarbon, an aromatic hydrocarbon, a heterocyclic hydrocarbon, a primary, secondary or tertiary amine, an ether, or the like as a basic skeleton, and two or more hydroxyl groups as a substituent.

Preferably, the polyol compound (α) further contains one, or two or more substituents selected from the group consisting of a carboxy group, a carbonyl group, an amino group, an ether bond, a thiol group and a thioether bond.

Preferably, the polyol compound (α) is selected from the group consisting of alkylpolyol, arylpolyol, polyalkanolamine, cyanuric acid and dipentaerythritol.

When the polyol compound (α) has 3 or more hydroxyl groups, not all the hydroxyl groups need to be reacted with (meth)acrylic acid and may be partially esterified. That is, these esters may have unreacted hydroxyl groups. Examples of such esters include a mixture consisting of one, or two or more selected from tris(2-acryloxyethyl) isocyanurate, dipentaerythritol hexa(meth)acrylate, tripentaerythritol octa(meth)acrylate, pentaerythritol tetra(meth)acrylate, dipropylene glycol diacrylate, tripropylene glycol diacrylate, trimethylolpropane triacrylate, polytetramethylene glycol dimethacrylate, trimethylolpropane trimethacrylate, ditrimethylolpropane tetraacrylate, tricyclodecane dimethanol diacrylate, 1,9-nonanediol diacrylate, 1,6-hexanediol diacrylate and 1,10-decanediol diacrylate.

Preferably, it is tris(2-acryloxyethyl) isocyanurate and dipentaerythritol hexaacrylate or a combination thereof.

More preferably, it is a combination of a compound containing three (meth)acryloyloxy groups and a compound containing two (meth)acryloyloxy groups.

Preferably, the molecular weight of the compound containing two or more (meth)acryloyloxy groups is 2,000 or less, more preferably 1,500 or less.

Preferably, the content of the compound containing two or more (meth)acryloyloxy groups is 5 to 99.9 mass %, more preferably 30 to 70 mass %, based on the total mass of the composition excluding the solvent.

Preferably, the alkali-soluble polymer is selected from the group consisting of (meth)acrylic polymer, siloxane polymer, siloxane (meth)acrylic polymer, and mixtures thereof.

The alkali dissolution rate of an alkali-soluble polymer is measured and calculated as follows, using a 0.03 mass % KOH aqueous solution as the alkali solution.

The alkali-soluble polymer is diluted with PGMEA to become 35 mass %, and dissolved at room temperature with stirring for 1 hour using a stirrer. In a clean room at a temperature of 23.0±0.5° C. and a humidity of 50±5.0%, 1 cc of the prepared alkali-soluble polymer solution is dropped onto the center portion of a silicon wafer (4-inch and thickness: 525 μm) using a pipette and spin-coated to become a thickness of 2±0.1 μm, followed by heating on a hot plate at 100° C. for 90 seconds to remove the solvent. The film thickness of the coating film is measured with a spectroscopic ellipsometer (J. A. Woollam).

Next, after the silicon wafer having this film is gently immersed in a 6-inch diameter glass petri dish containing 100 ml of a 0.03 mass % KOH aqueous solution adjusted to 23.0±0.1° C., it is left to stand, and the time until the coating film disappears is measured. The dissolution rate is obtained by dividing by the time required for the film at 10 mm inside from the edge of the wafer to disappear. When the dissolution rate is remarkably slow, after the wafer is immersed in a KOH aqueous solution for a certain period of time, the film thickness is measured, and the dissolution rate is calculated by dividing the amount of change in film thickness before and after the immersion by the immersion time. The above measurement method is performed 5 times, and the average of the obtained values is taken as the dissolution rate of the alkali-soluble polymer.

Preferably, the alkali-soluble polymer is referred to one in which the coating film at 10 mm inside from the edge of the wafer dissolves and disappears in a 0.03 mass % KOH aqueous solution within 10 minutes in the measurement and calculation of the alkali dissolution rate.

### Embodiment 7

The composition according to any one of Embodiments 1 to 6, wherein the alkali-soluble material (I) comprises a compound containing two or more (meth)acryloyloxy groups.

### Embodiment 8

The composition according to Embodiment 7, wherein the alkali-soluble material (I) further comprises an alkali-soluble polymer.

Preferably, the content of the compound containing two or more (meth)acryloyloxy groups is 5 to 1,000 mass %, more preferably 10 to 800 mass %, based on the total mass of the alkali-soluble polymer.

### Embodiment 9

The composition according to any one of Embodiments 1 to 8, further comprising a solvent (VI).

Preferably, the solvent (VI) is one or a combination of a plurality of any of ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether and propylene glycol monoethyl ether; propylene glycol alkyl ether acetates, such as PGMEA, propylene glycol monoethyl ether acetate and propylene glycol monopropyl ether acetate; aromatic hydrocarbons, such as benzene, toluene and xylene; ketones, such as methyl ethyl ketone, acetone, methyl amyl ketone, methyl isobutyl ketone and cyclohexanone; alcohols, such as ethanol, propanol, butanol, hexanol, cyclohexanol, ethylene glycol and glycerin; esters, such as ethyl lactate, ethyl 3-ethoxypropionate and methyl 3-methoxypropionate; cyclic esters, such as γ-butyrolactone, more preferably selected from propylene glycol alkyl ether acetates, esters, and alcohols having a straight or branched chain of an alkyl group with 4 or 5 carbon atoms. Preferably, the solvent contains 5 to 80 mass % of alcohol.

### Embodiment 10

The composition according to any one of Embodiments 1 to 9, further comprising an additive (VII).

Preferably, the additive (VII) is a developer dissolution accelerator (preferably a compound having a hydroxyl group, more preferably a monomer or polymer having a hydroxyl group, or mixture thereof), a scum remover, an adhesion enhancer, a polymerization inhibitor, an antifoaming agent, a third surfactant different from the first and second surfactants, a sensitizer, a crosslinker, a hardener, or a mixture thereof.

### Embodiment 11

A method for manufacturing a cured film comprising a step of applying the composition according to any one of Embodiments 1 to 10 above a substrate to form a coating film, and a step of heating the coating film.

Preferably, the method for manufacturing a cured film further comprises a step of exposing the coating film to light and a step of developing the coating film. More preferably, the method for manufacturing a cured film comprises a step of applying the composition according to any one of Embodiments 1 to 10 above a substrate to form a coating film, a step of exposing the coating film to light, a step of developing the coating film, and a step of heating in this order, and further preferably, further comprises a step of prebaking after the coating step and before the exposing step.

### Embodiment 12

A cured film manufactured or capable of being manufactured by the method according to Embodiment 11.

### Embodiment 13

A cured film comprising:
a polymer (A) derived from an alkali-soluble material,
a first surfactant; and
a second surfactant different from the first surfactant.

Preferably, the polymer (A) derived from an alkali-soluble material has a network crosslinked structure.

Preferably, the cured film is patterned. More preferably, the cured film is a patterned bank.

Preferably, the cured film further contains a coloring agent. More preferably, the coloring agent is an organic coloring agent and/or an inorganic coloring agent, further preferably the coloring agent is an organic and/or inorganic black coloring agent.

More preferably, the polymer (A) is a polymer derived from an alkali-soluble material (I) and a polymerization initiator (V).

### Embodiment 14

The cured film according to Embodiment 12 or 13, which has an average film thickness of 0.1 to 100 μm, preferably 1 to 50 μm, more preferably 1 to 25 μm, further preferably 5 to 20 μm.

### Embodiment 15

The cured film according to any one of Embodiments 12 to 14, wherein the upper part of the cured film is oil repellent and the lower part is lipophilic. Preferably the cured film is patterned, more preferably the cured film is a patterned bank.

### Embodiment 16

A light conversion device comprising the cured film according to any one of Embodiments 12 to 15.

### Embodiment 17

A display device comprising the cured film according to any one of Embodiments 12 to 15 or the light conversion device according to Embodiment 16.

### Embodiment 18

Use of a first surfactant (II) and a second surfactant (III) that is different from the first surfactant, into a composition comprising an alkali-soluble material (I).

Preferably, the composition is a photosensitive composition, more preferably a negative type photosensitive composition.

Preferably, the composition further comprises a coloring agent (IV), preferably an organic coloring agent and/or inorganic coloring agent, more preferably an organic and/or inorganic black coloring agent; a polymerization initiator (V); and/or a solvent (VI).

Preferably, the first surfactant (II) is a fluorine-free surfactant, more preferably a fluorine-free nonionic surfactant, anionic surfactant or amphoteric surfactant, or a mixture thereof, and the second surfactant (III) is a fluorine-containing surfactant.

The present invention is described in more particularly with reference to Examples and Comparative Examples below, but the present invention is not limited to these Examples and Comparative Examples.

### Comparative Example 1

In a PGMEA solution containing 100 parts by mass of a mixture of acrylic polymer A (Shin-Nakamura Chemical Co., Ltd.) and acrylic polymer B (Natoco Co., Ltd.) at a mass ratio of 3:1, each 3.0 parts by mass of polymerization initiator A (ADEKA Corporation “NCI-831”) and polymerization initiator B (IGM Resins B.V. “Omnirad 784”), 143 parts by mass of dipentaerythritol hexaacrylate (Shin-Nakamura Chemical Co., Ltd. “A-DPH”) as a (meth)acryloyloxy group-containing compound, 47 parts by mass of additive A (thiol monomer “Karenz MT PE-1”, Showa Denko K.K.), 39 parts by mass of coloring agent A (black coloring agent, Toyocolor Co., Ltd.) and 4.5 parts by mass of fluorine-containing surfactant A (Daikin Industries, Ltd.) are added, and further PGMEA is added to prepare a solution having a solid content ratio of 35 mass %, and the composition of Comparative Example 1 is obtained.

### Comparative Examples 2 to 5

Compositions of Comparative Examples 2 to 5 are prepared in the same manner as in Comparative Example 1, except that the composition is changed as shown in Table 1.

TABLE 1

| | | | Comparative Example | | | | |
|---|---|---|---|---|---|---|---|
| | | | 1 | 2 | 3 | 4 | 5 |
| Composition | (I) | (Meth)acryloyloxy group- | 143 | 143 | 143 | 143 | 143 |
| | Alkali-soluble | containing compound A | | | | | |
| | material | Acrylic polymer A | 75 | 75 | 75 | 75 | 75 |
| | | Acrylic polymer B | 25 | 25 | 25 | 25 | 25 |
| | (II)(III) | Surfactant A | 4.5 | — | — | — | — |
| | Surfactant | Surfactant B | — | 2.7 | — | 9 | — |
| | | Surfactant C | — | — | 0.9 | — | 9 |
| | (IV) | Coloring agent A | 39 | 39 | 39 | 39 | 39 |
| | Coloring agent | | | | | | |
| | (V) | Polymerization initiator A | 3 | 3 | 3 | 3 | 3 |
| | Polymerization | Polymerization initiator B | 3 | 3 | 3 | 3 | 3 |
| | initiator | | | | | | |
| | (VII) | Additive A | 47 | 47 | 47 | 47 | 47 |
| | Additive | | | | | | |
| Evaluation | Residue | | None | None | None | None | None |
| | OD | | 2.0 | 2.0 | 2.0 | 2.0 | 2.0 |
| | Surface free energy mJ/m² | | 14.8 | 15.1 | 15.8 | 24.8 | 27.9 |
| | Ink spreading | Bank 1 drop | OK | OK | OK | OK | OK |
| | | Hole 54 × 160 μm 1 drop | NG | NG | NG | NG | NG |
| | | Hole 200 × 200 μm 1 drop | NG | NG | NG | — | — |
| | | Hole 200 × 200 μm 10 drops | NG | NG | NG | — | — |
| | | Hole 200 × 200 μm 20 drops | NG | NG | NG | — | — |
| | | Hole 200 × 200 μm 40 drops | NG | NG | NG | — | — |
| | | Hole 200 × 200 μm 60 drops | NG | NG | NG | — | — |

### Examples 1 to 6

Compositions of Examples 1 to 6 are prepared in the same manner as in Comparative Example 1, except that the composition is changed as shown in Table 2.

TABLE 2

| | | | Example | | | | | |
|---|---|---|---|---|---|---|---|---|
| | | | 1 | 2 | 3 | 4 | 5 | 6 |
| Composition | (I) | (Meth)acryloyloxy group- | 143 | 143 | 143 | 143 | 143 | 143 |
| | Alkali-soluble | containing compound A | | | | | | |
| | material | Acrylic polymer A | 75 | 75 | 75 | 75 | 75 | 75 |
| | | Acrylic polymer B | 25 | 25 | 25 | 25 | 25 | 25 |
| | (II) (III) | Surfactant A | 0.9 | 0.9 | 0.9 | 0.9 | 0.9 | 0.9 |
| | Surfactant | Surfactant B | 0.09 | 0.27 | 0.54 | — | — | — |
| | | Surfactant C | — | — | — | 0.09 | 0.27 | 0.54 |
| | (IV) | Coloring agent A | 39 | 39 | 39 | 39 | 39 | 39 |
| | Coloring agent | | | | | | | |
| | (V) | Polymerization initiator A | 3 | 3 | 3 | 3 | 3 | 3 |
| | Polymerization | Polymerization initiator B | 3 | 3 | 3 | 3 | 3 | 3 |
| | (VII) | Additive A | 47 | 47 | 47 | 47 | 47 | 47 |
| | Additive | | | | | | | |
| Evaluation | Residue | | None | None | None | None | None | None |
| | OD | | 2.0 | 2.0 | 2.0 | 2.0 | 2.0 | 2.0 |
| | Surface free energy mJ/m² | | 17.7 | 23.8 | 27.4 | 16.3 | 23.6 | 16.3 |
| | Ink spreading | Bank 1 drop | OK | OK | OK | OK | OK | OK |
| | | Hole 54 × 160 μm 1 drop | OK | OK | OK | OK | OK | OK |
| | | Hole 200 × 200 μm 1 drop | NG | NG | NG | NG | NG | NG |
| | | Hole 200 × 200 μm 10 drops | NG | OK | OK | NG | OK | OK |
| | | Hole 200 × 200 μm 20 drops | NG | OK | OK | NG | OK | OK |
| | | Hole 200 × 200 μm 40 drops | NG | OK | OK | NG | OK | OK |
| | | Hole 200 × 200 μm 60 drops | NG | OK | OK | NG | OK | OK |

In Tables 1 and 2:
(Meth)acryloyloxy group-containing compound A: dipentaerythritol hexaacrylate “A-DPH” (Shin-Nakamura Chemical Co., Ltd.)
Acrylic polymer A: acrylic random polymer made from carboxyl acid monomer and monomer containing at least one aromatic ring group (Shin-Nakamura Chemical Co., Ltd.).
Acrylic polymer B: 2-propenoic acid, 2-methyl-, polymer with 2-hydroxyethyl 2-methyl-2-propenoate, 2-isocyanatoethyl 2-propenoate and methyl 2-methyl-2-propenoate (Natoco Co., Ltd.)
Polymerization initiator A: “NCI-831” (ADEKA Corporation)
Polymerization initiator B: “Omnirad 784” (IGM Resins B.V.)
Additive A: thiol monomer A “Karenz MT PE-1” (Showa Denko K.K.)
Coloring agent A: black pigment (Toyocolor Co., Ltd.)
Surfactant A: fluorine-containing surfactant (Daikin Industries, Ltd.) As the surfactant A, for example, Surflon (AGC Seimi Chemical Co., Ltd.), which is a surfactant having a perfluoroalkyl group, can also be used.
Surfactant B: silicon-based surfactant (DIC Corporation) As the surfactant B, for example, silicon-based surfactant SOILNON AF-800 (Nicca Chemical Co., Ltd.) can also be used.
Surfactant C: “Glide ZG400” (Evonik Industries)

### (Pattern Forming)

Each of the resulting compositions is applied onto a glass substrate by a spin coater (MS-A100, MIKASA), and after applying, it is subjected to prebaking on a hot plate (HHP-411V, AS ONE) at 60° C. for 90 seconds to adjust the average thickness becomes 10 μm. Exposure is performed using an i-line exposure machine (NES2W-ghi06, Nikon), and hole patterns of 54×160 and 200×200 μm are formed using a 0.03 mass % KOH aqueous solution as a developer. The patterned substrate is placed in an oven (DP-200, Yamato) at 85° C. and heated for 30 minutes to accelerate curing of the polymer. The pattern is checked with an optical microscope (MX61A, OLYMPUS) and SEM (JSM-7100, JEOL) to confirm that there is no residue.

### (Optical Density Measurement)

An unpatterned substrate is prepared for optical density measurement. In the step of exposing, the entire surface of the substrate is exposed without using any photomask. In other steps, a film is formed by the same process procedure as the pattern forming. A transmission spectrum is measured with a spectrophotometer (CM-5, KONICA MINOLTA), and an average OD value in the wavelength range of 400 to 650 nm is calculated.

### (Surface Free Energy Measurement)

An unpatterned substrate is prepared for surface free energy measurement. In the step of exposing, the entire surface of the substrate is exposed without using any photomask. In other steps, a film is formed by the same process procedure as the pattern forming. The formed substrate is set in a contact angle meter (DropMaster700, Kyowa), and the contact angle between distilled water and 3 μL of diiodomethane is measured. The surface free energy is calculated from the Owens-Wendt theoretical formula and the value of the obtained contact angle.

### (Ink Production)

Ink A is formed by mixing the materials listed in Table 3 below. With respect to inks, they can also be formed using materials and methods described, for example, in WO2021/116139A1.

TABLE 3

| | | |
|---|---|---|
| Green emission InP/ZnSe/ZnS QD | 40.0 | mass % |
| LA + HDDA (LA:HDDA = 80:20) | 52.5 | mass % |
| monomer mixture | | |
| TiO₂ particles (scattering particles) | 6 | mass % |
| Phenylbis(2,4,6-trimethylbenzoyl) | 1.0 | mass % |
| phosphine oxide (Omnirad 819) | | |
| Irganox 1010 | 0.5 | mass % |

In the table, the method for forming the monomer mixture is as follows.

Prior to use, 1,6-hexanediol diacrylate (HDDA) is passed through a molecular sieve to be treated for high-purification. Next, 2 g of HDDA that has been treated for high-purification and 8 g of lauryl acrylate (LA, viscosity: 4.0 cP, BP: 313.2° C.) are mixed in a glass vial (HDDA:LA=2:8) to obtain a monomer mixture.

### (Test of Ink Spreading)

A drop of ink A is put in a hole pattern with a size of 54×160 μm using an inkjet printer (Dimatix DMP-2831, FujiFilm), and the spread of the ink is evaluated with an optical microscope and SEM.

In hole patterns with a size of 200×200 μm, 10, 20, 40, 60 drops of ink A are put and the spread of the ink are observed with an optical microscope (VK-X1000, KEYENCE) and SEM (JSM-7100, JEOL).

In the evaluations in Tables 1 and 2, if the ink does not spread on the pattern and the droplet shape is maintained (that is, if the ink is repelled), it is evaluated as OK, and if the droplet cannot be maintained, it is evaluated as NG. In the hole, when the droplet shape is maintained, it is evaluated as NG, and when the ink spreads in the hole without becoming a droplet, it is evaluated as OK.

1.-16. (canceled)

17. A composition comprising:
(I) an alkali-soluble material;
(II) a first surfactant; and
(III) a second surfactant different from the first surfactant.

18. The composition according to claim 17, wherein the first surfactant (II) is a surfactant that exhibits lipophilicity and the second surfactant (III) is a surfactant that exhibits oil repellency.

19. The composition according to claim 17, wherein the mass ratio of the first surfactant (II) to the second surfactant (III) (the first surfactant (II):the second surfactant (III)) is 1:1,000 to 99:10.

20. The composition according to claim 17, wherein the content of the first surfactant (II) is 0.001 to 5 mass % based on the total mass of the alkali-soluble material (I).

21. The composition according to claim 17, further comprising a coloring agent (IV).

22. The composition according to claim 17, wherein the alkali-soluble material (I) is a compound containing two or more (meth)acryloyloxy groups and/or an alkali-soluble polymer.

23. The composition according to claim 17, wherein the alkali-soluble material (I) comprises a compound containing two or more (meth)acryloyloxy groups.

24. The composition according to claim 23, wherein the alkali-soluble material (I) further comprises an alkali-soluble polymer.

25. The composition according to claim 17, further comprising a solvent (VI).

26. A method for manufacturing a cured film comprising:
a step of applying the composition according to claim 17 above a substrate to form a coating film; and
a step of heating the coating film.

27. A cured film manufactured or capable of being manufactured by the method according to claim 26.

28. A cured film comprising:
a polymer (A) derived from an alkali-soluble material;
a first surfactant; and
a second surfactant different from the first surfactant.

29. The cured film according to claim 27, which has an average film thickness of 0.1 to 100 μm.

30. The cured film according to claim 27, wherein the upper part of the cured film is oil repellent and the lower part is lipophilic.

31. A light conversion device comprising the cured film according to claim 27.

32. A display device comprising the cured film according to claim 27.
